(19) United States
(12) Patent Application Publication
(10) Pub. No.: US 2015/0041916 A1
(43) Pub. Date: Feb. 12, 2015

(54) SEMICONDUCTOR DEVICE AND METHOD OF FORMING THE SAME

(71) Applicant: SAMSUNG ELECTRONICS CO., LTD., Suwon-si (KR)

(72) Inventors: Cheong Sik YU, Seoul (KR); Cheolhwyi BAE, Gunpo-si (KR); JeeHoo PARK, Hwaseong-si (KR); Seung Chul LEE, Seongnam-si (KR)

(73) Assignee: SAMSUNG ELECTRONICS CO., LTD., Suwon-si (KR)

(21) Appl. No.: 13/962,285

(22) Filed: Aug. 8, 2013

(51) Int. Cl. H01L 27/11; H01L 29/78

(52) U.S. Cl. CPC H01L 27/1104; H01L 29/78
USPC 257/392

(57) ABSTRACT

A co-implant concentration of a source region of a pull-down transistor is higher than those of other co-implant concentrations. Thus, dopants in a halo region of the source region may be prevented from excessively being diffused into a channel region during a post annealing process. As a result, dispersion of saturation threshold voltages of unit memory cells may be reduced.

### TECHNICAL FIELD

The inventive concept relates to a semiconductor device and a method of forming the same.

### DISCUSSION OF RELATED ART

Semiconductor memory devices may be classified into dynamic random access memory (DRAM) devices and static random access memory (SRAM) devices according to storage modes thereof. SRAM devices feature fast speed, low power consumption and simple operation. Additionally, the SRAM devices operate without a refresh operation periodically restoring data, unlike the DRAM devices.

SRAM devices include memory cell transistors configured to be a latch to store data. As SRAM devices are getting smaller, random variation of threshold voltage (Vth) of memory cell transistors may affect stability of SRAM devices.

### SUMMARY

According to an exemplary embodiment of the present inventive concept, a semiconductor is provided. The semiconductor includes a first low concentration dopant region and a second low concentration dopant region disposed in the substrate. The first low concentration is disposed on one side of the first gate electrode and the second low concentration is disposed on the other side of the first gate electrode. First spacers cover both sidewalls of the first gate electrode. A first high concentration dopant region and a second high concentration dopant region are disposed in the substrate and are adjacent to sidewalls of the first spacers. A first halo region and a second halo region are disposed in the substrate and are disposed under the first gate electrode. The first and second halo regions are in contact with the first and second low concentration dopant regions, respectively. A first co-implant is implanted into the first halo region with a first concentration. A second co-implant is implanted into the second halo region with a second concentration. The first concentration is different from the second concentration.

According to an exemplary embodiment of the present inventive concept, a fabrication method of forming a semiconductor is provided. A first gate electrode and a second gate electrode are formed on a substrate and are spaced apart from each other. A first ion implantation process is performed using the first and the second gate electrodes as an implantation mask to form first and second low concentration dopant regions on opposing sides of the first gate electrode and form third and fourth low concentration dopant regions on opposing sides of the second gate electrode. A second ion implantation process is performed to form first and second halo regions respectively contacting the first and second low concentration dopant regions under the first gate electrode and form third and fourth halo regions respectively contacting the third and fourth low concentration dopant regions under the second gate electrode. A third ion implantation process is performed using a first ion implantation mask to implant a first co-implant into the first halo region. A fourth ion implantation process is performed using a second ion implantation mask to implant a second co-implant into the second through fourth halo regions.

According to an exemplary embodiment of the present inventive concept, a fabrication method of forming a semiconductor is provided. A gate electrode is formed a substrate. A first low concentration dopant region is formed on one side of the gate electrode, and a second low concentration dopant region is formed on the other side of the gate electrode. A first halo region is in contact with the first low concentration dopant region, and a second halo region is in contact with the second low concentration dopant region. A first co-implant implantation process is performed using a first ion implantation mask to implant a first co-implant into the first halo region with a first concentration. A second co-implant implantation process is performed using a second ion implantation mask to implant a second co-implant into the second halo region with a second concentration.

### BRIEF DESCRIPTION OF THE DRAWINGS

These and other features of the inventive concept will become more apparent by describing in detail exemplary embodiments thereof with reference to accompanying drawings of which:

FIG. 1 is a circuit diagram illustrating a semiconductor device according to an exemplary embodiment of the inventive concept;

FIG. 2 is a plan view illustrating a semiconductor device according to an exemplary embodiment of the inventive concept;

FIG. 3 is a cross-sectional view taken along line I-I′ of FIG. 2;

FIGS. 4 to 10 and 12 are cross-sectional views illustrating a method of forming a semiconductor device of FIG. 3 according to an exemplary embodiment of the inventive concept;

FIG. 11 is a plan view illustrating a part of a method of forming a semiconductor device according to an exemplary embodiment of the inventive concept;

FIG. 13 is a schematic block diagram illustrating an example of electronic devices including a semiconductor device according to an exemplary embodiment of the inventive concept; and

FIG. 14 is a schematic block diagram illustrating an example of memory systems including a semiconductor device according to an exemplary embodiment of the inventive concept.

### DETAILED DESCRIPTION OF THE EMBODIMENTS

Exemplary embodiments of the inventive concept will be described below in more detail with reference to the accompanying drawings. However, the inventive concept may be embodied in different forms and should not be construed as limited to the embodiments set forth herein. In the drawings, the thickness of layers and regions may be exaggerated for clarity. Like reference numerals may refer to the like elements throughout the specification and drawings.

The terminology used herein is for the purpose of describing particular embodiments only and is not intended to limit the inventive concept. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it may be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third etc., may be used herein to describe various elements, these elements should not be limited by these terms. These terms are only used to distinguish one element from another element. Thus, a first element in some exemplary embodiments could be termed a second element in other exemplary embodiments without departing from the teachings of the present invention. Exemplary embodiments of aspects of the present inventive concept explained and illustrated herein include their complementary counterparts. The same reference numerals or the same reference designators may denote the same elements throughout the specification and drawings.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etched region illustrated as a rectangle will, typically, have rounded or curved features. Thus, the regions illustrated in the figures are schematic in nature and their shapes are not intended to illustrate the actual shape of a region of a device and are not intended to limit the inventive concept.

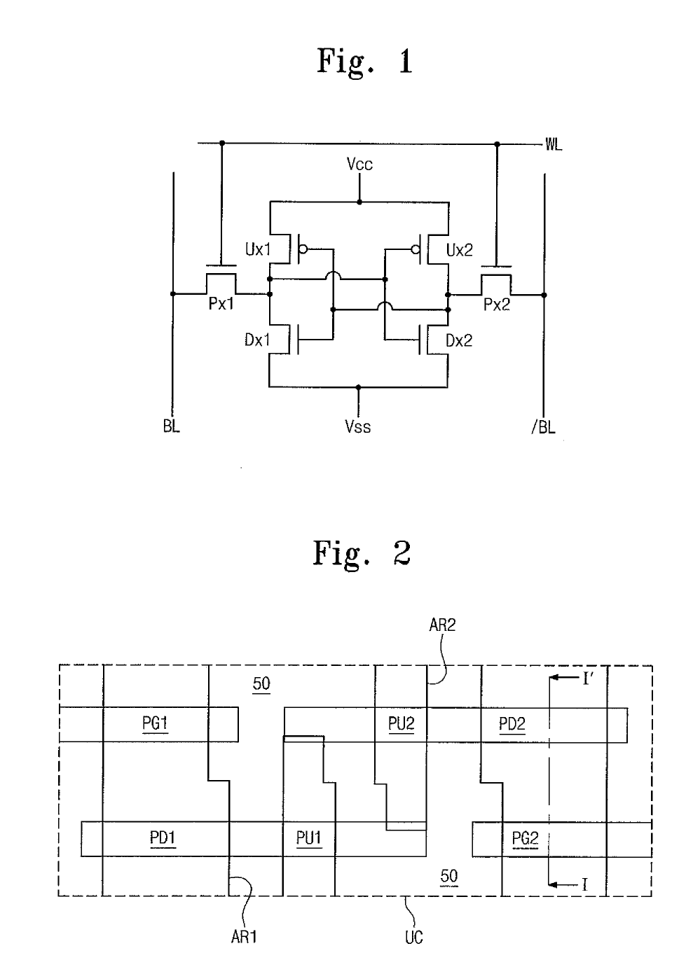

FIG. 1 is a circuit diagram illustrating a semiconductor device according to an exemplary embodiment of the inventive concept.

Referring to FIG. 1, a semiconductor device according to an exemplary embodiment of the inventive concept is a unit cell of a static random access memory (SRAM) device. The unit cell of the semiconductor device includes two complementary metal-oxide semiconductor (CMOS) inverters cross-coupled to constitute a flip-flop circuit serving as memory nodes. The unit cell further includes pass transistors Px1 and Px2 for reading/writing data from/in the memory nodes. The two CMOS inverters include two pull-down transistors Dx1 and Dx2 and two pull-up transistors Ux1 and Ux2 which constitute the flip-flop circuit as illustrated in FIG. 1. The pass transistors Px1 and Px2 are connected to a word line WL and bit lines BL and /BL.

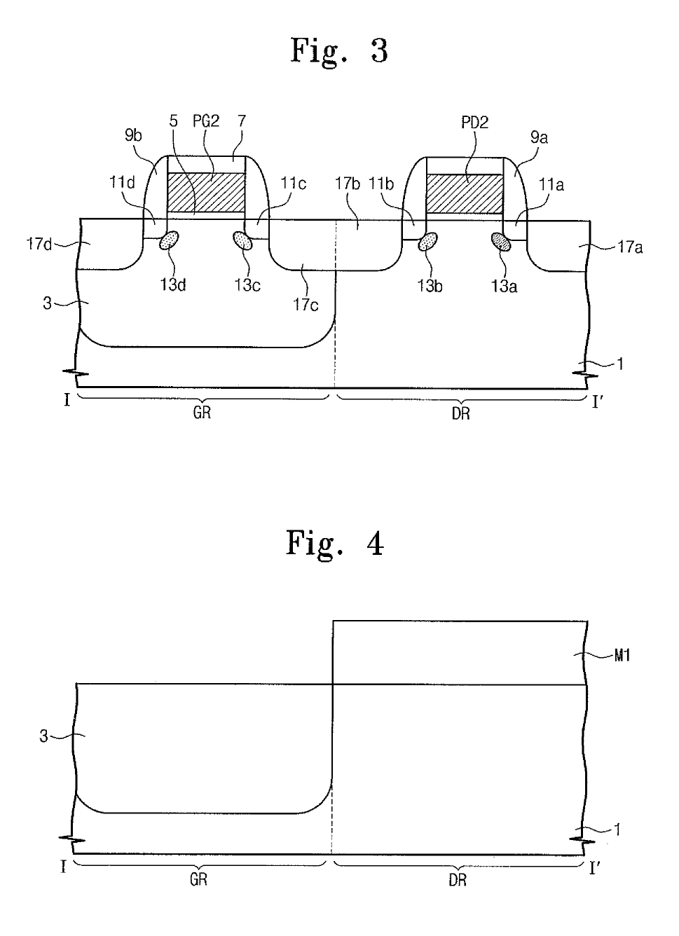

FIG. 2 is a plan view illustrating a semiconductor device according to an exemplary embodiment of the inventive concept. FIG. 3 is a cross-sectional view taken along line I-I′ of FIG. 2.

A device isolation layer 50 is disposed in or on a semiconductor substrate 1 (hereinafter, referred to as ‘a substrate’) to define active regions AR1 and AR2. In a unit memory cell region UC, pull-down gate electrodes PD1 and PD2 are disposed on first active regions AR1, respectively. Pass gate electrodes PG1 and PG2 are disposed on the first active regions AR1. For example, the first active regions AR1 are active regions for N-type field effect transistors. Pull-up gate electrodes PU1 and PU2 are disposed on second active regions AR2. For example, the second active regions AR2 are active regions for P-type field effect transistors.

The first active region AR1 includes a first region DR and a second region GR. The first region DR is a region where the pull-down transistor PD2 is formed, and the second region GR is a region where the pass transistor PG2 is formed. A gate insulating pattern 5 is disposed between the pull-down gate electrode PD2 and the substrate 1 and between the pass gate electrode PG2 and the substrate 1. A capping pattern 7 is disposed on each of the pull-down and the pass gate electrodes PD2 and PG2. A first spacer 9a covers both sidewalls of the pull-down gate electrode PD2, and a second spacer 9b covers both sidewalls of the pass gate electrode PG2. The substrate 1 of the first active region AR1 is doped with, for example, P-type dopants. A pocket well region 3 is formed in the second region GR. The pocket well region 3 is doped with, for example, P-type dopants. A concentration of P-type dopants in the pocket well region 3 is higher than a concentration of P-type dopants in the substrate 1. A dopant concentration of a channel region under the pass gate electrode PG2 is higher than a dopant concentration of a channel region under the pull-down gate electrode PD2.

A first low concentration dopant region 11a is disposed in the substrate 1 at one side of the pull-down gate electrode PD2 and, and a second low concentration dopant region 11b is disposed in the substrate 1 at the other side of the pull-down gate electrode PD2. A first high concentration dopant region 17a and a second high concentration dopant region 17b are disposed in the substrate 1 adjacent to the first spacers 9a covering the both sidewalls of the pull-down gate electrode PD2, respectively. The first high concentration dopant region 17a corresponds to a source region of the pull-down transistor Dx2. The second high concentration dopant region 17b corresponds to a drain region of the pull-down transistor Dx2. A first halo region 13a and a second halo region 13b are disposed in the substrate 1 under the pull-down gate electrode PD2. The first and second halo regions 13a and 13b are in contact with the first and second low concentration dopant regions 11a and 11b, respectively.

A third low concentration dopant region 11c is disposed in the substrate 1 at one side of the pass gate electrode PG2, and a fourth low concentration dopant region 11d is disposed in the substrate 1 at the other side of the pass gate electrode PG2. A third high concentration dopant region 17c and a fourth high concentration dopant region 17d are disposed in the substrate 1 adjacent to the second spacers 9b covering the both sidewalls of the pass gate electrode PG2, respectively. A third halo region 13c and a fourth halo region 13d are disposed in the substrate 1 under the pass gate electrode PG2. The third and fourth halo regions 13c and 13d are in contact with the third and fourth low concentration dopant regions 11c and 11d, respectively.

The low concentration dopant regions 11a to 11d and the high concentration dopant regions 17a to 17d are doped with, for example, N-type dopants. The low concentration dopant regions 11a to 11d have dopant concentrations lower than those of the high concentration regions 17a to 17d. The low concentration dopant regions 11a to 11d are shallower than the high concentration dopant regions 17a to 17d. All of the halo regions 13a to 13d are doped with P-type dopants. The halo regions 13a to 13d have dopant concentrations higher than that of the pocket well region 3. For example, the halo regions 13a to 13d may be doped with P-type dopants (e.g., boron). In an exemplary embodiment, the halo regions 13a to 13d may have substantially the same P-type dopant concentration as each other. Alternatively, the first halo region 13a may have the lower P-type dopant concentration than the halo regions 13a to 13d, and the P-type dopant concentrations of the second to fourth halo regions 13b to 13d may be substantially equal to each other. The halo regions 13a to 13d are implanted with co-implants such as carbon, nitrogen or fluorine. The P-type dopants are clustered with the co-implants. For example, the boron dopants are clustered with carbon co-implants to form boron-carbon clusters which are not easy to diffuse. This prevents P-type dopants in the halo regions 13a to 13d from being diffused into the channel regions under the gate electrodes PD2 and PG2, respectively, during a post annealing process. A co-implant concentration of the first halo region 13a is higher than co-implant concentrations of the second through fourth halo regions 13b-13d. The co-implant concentrations of the second through fourth halo regions 13b-13d may be substantially the same as each other.

In a SRAM device, dispersion of saturation threshold voltages of memory cells (e.g., pull-down transistors) may increase, such that read/write operation failure and/or data storage failure may be caused. During a post annealing process, dopants in a halo region of a source region of the pull-down transistor may be excessively diffused into a channel region, such that the dispersion of the saturation threshold voltages may increase. However, the co-implant concentration of the first halo region 13a is higher than the co-implant concentrations of the second through fourth halo regions 13b-13d, and the co-implant concentration of the first halo region 13a may serve to prevent the P-type dopants in the first halo region 13a from being excessively diffused into the channel region. Thus, the dispersion of the saturation threshold voltages of unit memory cells may be reduced.

Next, a method of forming the semiconductor device will be described with reference to FIGS. 4 to 12. FIGS. 4 to 10 and 12 are cross-sectional views illustrating a method of forming a semiconductor device of FIG. 3 according to an exemplary embodiment of the inventive concept. FIG. 11 is a plan view illustrating a method of forming a semiconductor device according to an exemplary embodiment of the inventive concept.

Referring to FIG. 4, a first ion implantation mask pattern M1 is formed on a substrate 1 including a first region DR and a second region GR. The first ion implantation mask pattern M1 exposes the second region GR and covers other regions. A pocket well region 3 is formed in the second region GR by using an ion implantation process with the first ion implantation mask pattern M1. The pocket well region 3 is doped with P-type dopants (e.g., boron)

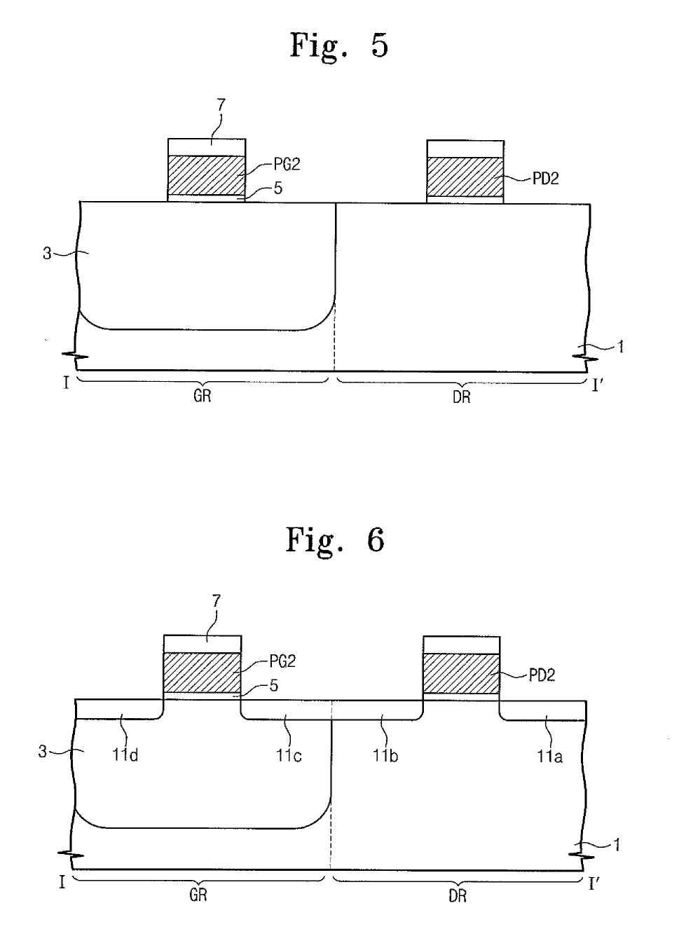

Referring to FIG. 5, the first ion implantation mask pattern M1 is removed. A gate insulating layer, a conductive layer, and a capping layer may be sequentially formed on the substrate 1. The capping layer, the conductive layer, and the gate insulating layer may be patterned to form a pull-down gate electrode PD2 and a pass gate electrode PG2 in the first region DR and the second region GR, respectively. Capping patterns 7 are formed on the pull-down gate electrode PD2 and the pass gate electrode PG2, respectively. Gate insulating patterns 5 are formed between the substrate I and the pass gate electrode PG2 and between the substrate 1 and the gate electrode PD2.

Referring to FIG. 6, first, second, third, and fourth low concentration dopant regions 11a, 11b, 11c, and 11d are formed using the capping patterns 7 as ion implantation masks in the first and second regions DR and GR, for example by implanting N-type dopants. The first and second low concentration dopant regions 11a and 11b are formed in the substrate 1 of the first region DR, and the third and fourth low concentration dopant regions 11c and 11d are formed in the substrate 1 of the second region GR.

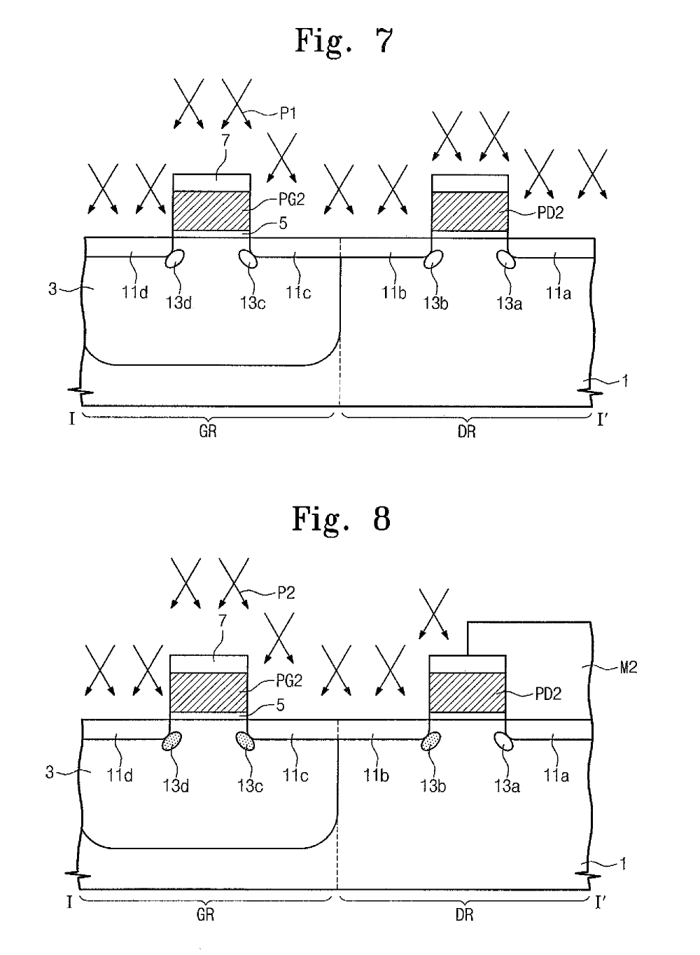

Referring to FIG. 7, a first tilt ion implantation process P1 is performed using the gate electrodes PD2 and PG2 as ion implantation masks and implanting P-type dopants to form first, second, third, and fourth halo regions 13a, 13b, 13c, and 13d which are in contact with the first, second, third, and fourth low concentration dopant regions 11a, 11b, 11c, and 11d, respectively. Alternatively, the first halo region 13a and the other halo regions 13b to 13d may be separately formed by different tilt ion implantation process in order to make the P-type dopant concentration of the first halo region 13a lower than the other halo regions 13b-13d.

Referring to FIG. 8, a second ion implantation mask pattern M2 is formed on the substrate 1. The second ion implantation mask pattern M2 exposes the second, third, and fourth low concentration dopant regions 11b, 11c, and 11d but covers the first low concentration dopant region 11a. A second tilt ion implantation process P2 is performed using the second ion implantation mask pattern M2 to implant co-implants into the second through fourth halo regions 13b˜13d. The second tilt ion implantation process P2 uses ions of co-dopants including carbon, nitrogen, and/or fluorine.

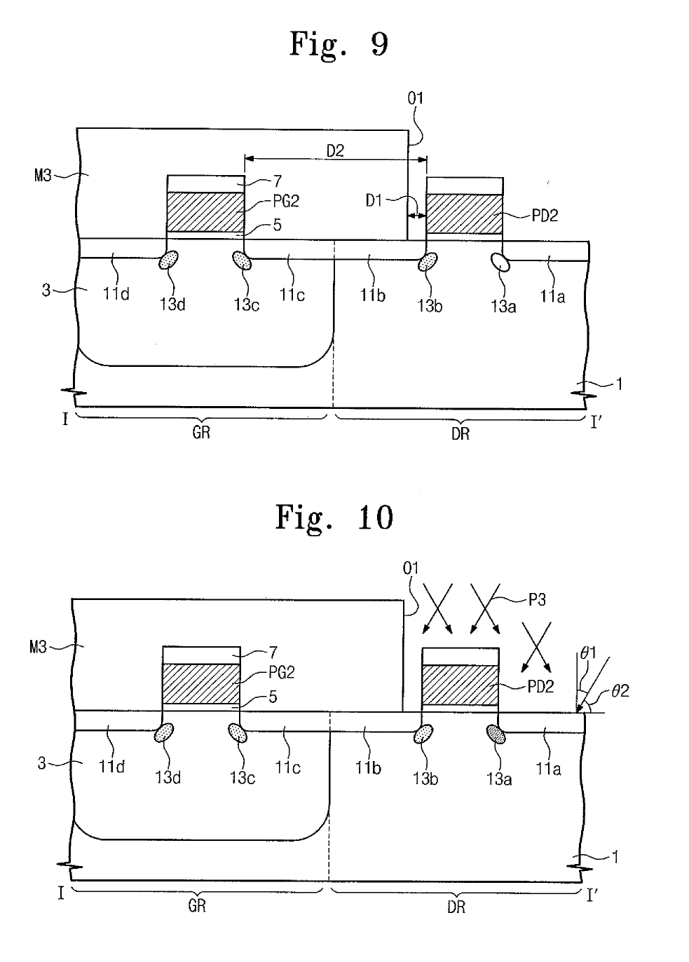

Referring to FIG. 9, the second ion implantation mask pattern M2 is removed. A third ion implantation mask pattern M3 is formed on the substrate 1. The third ion implantation mask pattern M3 may cover at least the pass gate electrode PG2 and the third and fourth low concentration dopant regions 11c and 11d. For example, the third ion implantation mask pattern M3 covers the pass gate electrode PG2 and the third and fourth low concentration dopant regions 11c and 11d and has a first opening O1 exposing the pull-down gate electrode PD2 and the first low concentration dopant region 11a. At this time, a first distance D1 between a sidewall of the third ion implantation mask pattern M3 and a sidewall of the pull-down gate electrode PD2 may be substantially equal to or smaller than a half of a second distance D2 between the pull-down gate electrode PD2 and the pass gate electrode PG2.

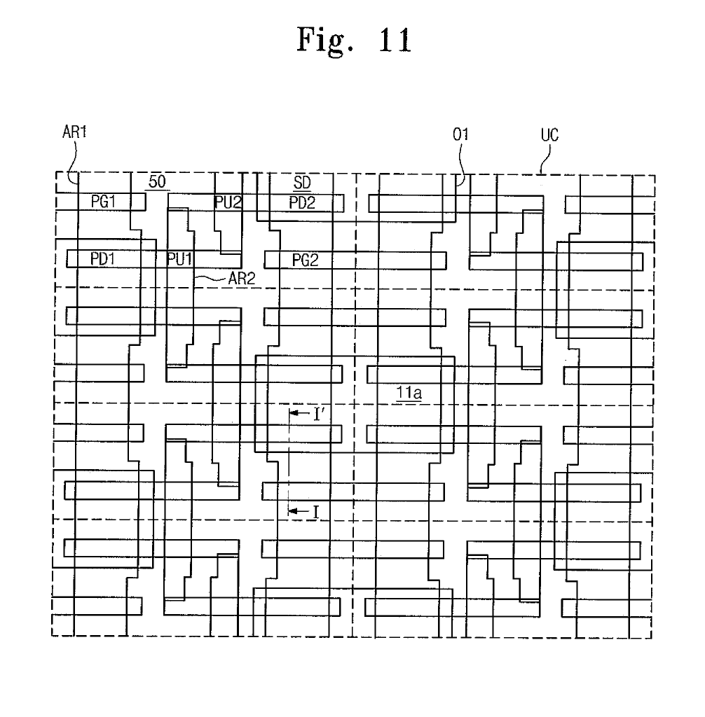

Referring to FIG. 10, a third tilt ion implantation process P3 is performed using the third ion implantation mask pattern M3 to implant a co-implant into the first halo region 13a. The third tilt ion implantation process P3 uses ions of co-dopants including carbon, nitrogen, and/or fluorine. The co-implant concentration of the first halo region 13a is higher than the co-implant concentrations of the second through fourth halo regions 13b˜13d. The co-implants are clustered with the P-type dopants in the halo regions 13a˜13d. The ions of the third tilt ion implantation process P3 are implanted at a first angle θ1 of about 5 degrees or more with respect to a direction perpendicular to a top surface of the substrate 1, or at a second angle θ2 of 85 degrees or less with respect to the top surface of the substrate 1. Since the ions are slantingly implanted in the third tilt ion implantation process P3, the ions are not implanted through the narrow space between the third ion implantation mask pattern M3 and the pull-down gate electrode PD2.

As shown in FIG. 11, the unit memory cell region UC of FIG. 2 is repeatedly arrayed along a first direction and a second direction crossing the first direction in a mirror-symmetric manner when viewed from a top view. Thus, the first opening O1 exposes the pull-down gate electrodes PD1 and PD2 adjacent to each other at the same time.

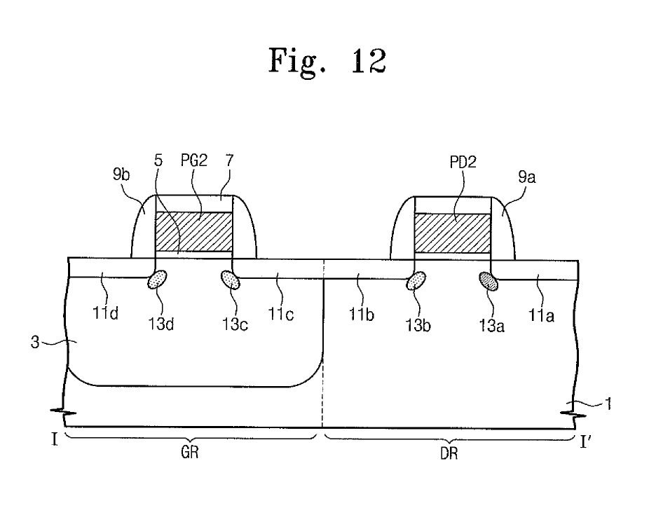

Referring to FIG. 12, the third ion implantation mask pattern M3 is removed. Subsequently, first and second spacers 9a and 9b are formed to cover sidewalls of the pull-down gate electrode PD2 and the pass gate electrode PG2, respectively.

Referring again to FIG. 3, first to fourth high concentration dopant regions 17a to 17d are formed by an ion implantation process using the capping patterns 7 and the first and second spacers 9a and 9b as ion implantation masks.

Subsequently, a post annealing process may be performed. At this time, the boron-carbon clusters prevent boron dopants in the halo regions 13a to 13d from being diffused into the channel regions under the gate electrodes PD2 and PG2, respectively. Since the co-implant concentration of the first halo region 13a is higher than the co-implant concentrations of the second through fourth halo regions 13b˜13d, it is possible to surely prevent the P-type dopants in the first halo region 13a from being excessively diffused into the channel region. Thus, the dispersion of the saturation threshold voltages of unit memory cells may be reduced.

The inventive concept is not limited to the order of the ion implantation processes as described above, but may be implemented in various orders.

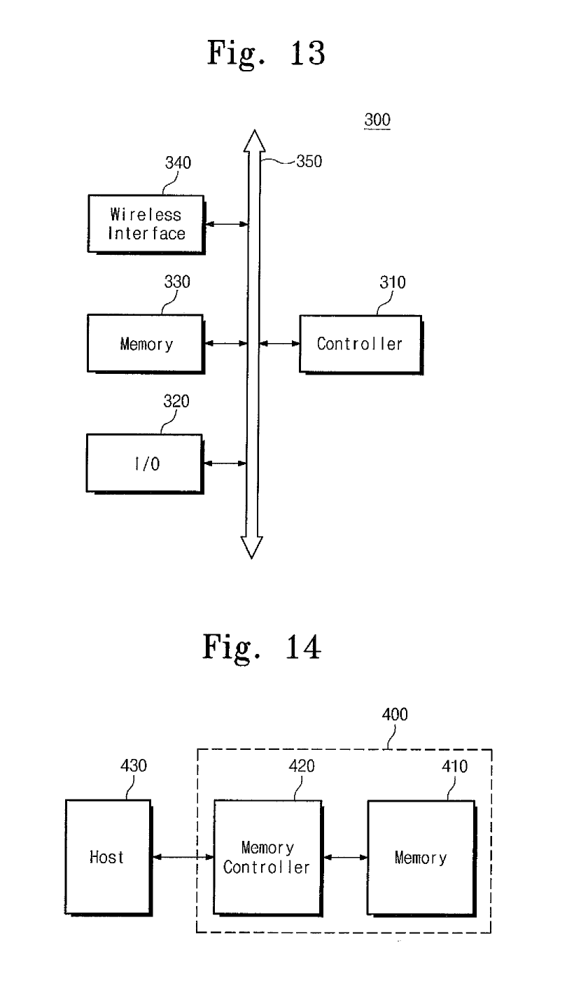

FIG. 13 is a schematic block diagram illustrating an example of electronic devices including a semiconductor device according to an exemplary embodiment of the inventive concept. FIG. 14 is a schematic block diagram illustrating an example of memory systems including a semiconductor device according to an exemplary embodiment of the inventive concept.

Referring to FIG. 13, an electronic device 300 including a semiconductor device according to an exemplary embodiment will be described. The electronic device 300 may be used as wireless communication devices, for example, a personal digital assistant (PDA), a laptop computer, a portable computer, web tablet, a wireless phone, a mobile phone, a digital music player, or other devices capable of transmitting/receiving information in a wireless environment.

The electronic device 300 includes a controller 310, an input/output (I/O) unit 320 such as a keypad, a keyboard and/or a display, a memory device 330, and wireless interface unit 340 which are combined with each other through a data bus 350. For example, the controller 310 may include a microprocessor, a digital signal processor, a microcontroller and/or other logic devices. The other logic devices may have a similar function to any one of the microprocessor, the digital signal processor and the microcontroller. The memory device 330 may store, for example, commands performed by the controller 310. Additionally, the memory device 330 may be used for storing a user data. The memory device 330 may includes a semiconductor device according to an exemplary embodiment of the inventive concept.

The electronic device 300 may use the wireless interface unit 340 for transmitting data to a wireless communication network communicating with a radio frequency (RF) signal or receiving data from the network. For example, the wireless interface unit 340 may include an antenna or a wireless transceiver.

The electronic device 300 according to an exemplary embodiment of inventive concept may be used in a communication interface protocol such as a third generation communication system (e.g., CDMA, GSM, NADC, E-TDMA, WCDAM, and/or CDMA2000).

Referring to FIG. 14, a semiconductor device according to an exemplary embodiment may be applied to a memory system 400.

The memory system 400 includes a memory device 410 for storing massive data and a memory controller 420. The memory controller 420 may read or write data from/into the memory device 410 in response to read/write request of a host 430. The memory controller 420 may include an address mapping table for mapping an address provided from the host 430 (e.g., a mobile device or a computer system) into a physical address of the memory device 410. The memory device 410 may include a semiconductor device according to an exemplary embodiment of the inventive concept.

In an exemplary embodiment, the co-implant concentration of the source region of the pull-down transistor is higher than other co-implant concentrations of the other regions. Thus, P-type dopants in the halo region of the source region may be prevented from excessively being diffused into the channel region during a post annealing process. As a result, the dispersion of the saturation threshold voltages of the unit memory cells may be reduced.

While the present inventive concept has been shown and described with reference to exemplary embodiments thereof, it will be apparent to those of ordinary skill in the art that various changes in form and detail may be made therein without departing from the spirit and scope of the inventive concept as defined by the following claims.

1. A semiconductor device comprising:
a first gate electrode on a substrate;
a first low concentration dopant region and a second low concentration dopant region disposed in the substrate, wherein the first low concentration is disposed on one side of the first gate electrode and the second low concentration is disposed on the other side of the first gate electrode;
first spacers covering both sidewalls of the first gate electrode;
a first high concentration dopant region and a second high concentration dopant region disposed in the substrate and adjacent to sidewalls of the first spacers; and
a first halo region and a second halo region disposed in the substrate and disposed under the first gate electrode, the first and second halo regions being in contact with the first and second low concentration dopant regions, respectively,
wherein a first co-implant is implanted into the first halo region with a first concentration,
wherein a second co-implant is implanted into the second halo region with a second concentration,
wherein the first concentration is different from the second concentration.

2. The semiconductor device of claim 1, wherein the⁻first and the second co-implant includes carbon, nitrogen, or fluorine.

3. The semiconductor device of claim 1, further comprising:
a second gate electrode spaced apart from the first gate electrode on the substrate;
a third low concentration dopant region and a fourth low concentration dopant region disposed in the substrate, wherein the third low concentration dopant region is disposed at one side of the second gate electrode and the fourth low concentration dopant region is disposed at the other side of the second gate electrode;
second spacers covering both sidewalls of the second gate electrode;
a third high concentration dopant region and a fourth high concentration dopant region disposed in the substrate and adjacent to sidewalls of the second spacers; and
a third halo region and a fourth halo region disposed in the substrate and disposed under the second gate electrode, the third and fourth halo regions being in contact with the third and fourth low concentration dopant regions, respectively,
wherein a third co-implant is implanted into the third halo region with a third concentration,
wherein a fourth co-implant is implanted into the fourth halo region with a fourth concentration,
wherein the third concentration is substantially equal to the fourth concentration.

4. The semiconductor device of claim 3, wherein the third concentration is substantially equal to the second concentration.

5. The semiconductor device of claim 3, wherein the first through fourth low concentration dopant regions are doped with first dopants of a first conductivity type,
wherein the first through fourth halo regions are doped with second dopants of a second conductivity type,
a concentration of the second dopant of the first halo region is different from concentrations of the second dopants of the second, third and fourth halo regions.

6. The semiconductor device of claim 3, further comprising:
a first channel region disposed in the substrate and disposed under the first gate electrode; and
a second channel region disposed in the substrate and disposed under the second gate electrode,
wherein a concentration of the first channel region is different from a concentration of the second channel region.

7. The semiconductor device of claim 3, wherein the semiconductor device is a static random access memory (SRAM) device;
wherein the first gate electrode is a pull-down gate electrode;
wherein the second gate electrode is a pass gate electrode;
wherein the first high concentration dopant region is a pull-down source region; and
wherein the first concentration is higher than the second through fourth concentrations.

8-18. (canceled)
